(19) United States
(12) Patent Application Publication
(10) Pub. No.: US 2026/0190397 A1
(43) Pub. Date: Jul. 2, 2026

(54) SEMICONDUCTOR DEVICE AND METHOD OF FABRICATING THE SAME

(71) Applicant: TAIWAN SEMICONDUCTOR MANUFACTURING COMPANY LTD., HSINCHU (TW)

(72) Inventor: YA-LING LEE, HSINCHU CITY (TW)

(21) Appl. No.: 19/006,295

(22) Filed: Dec. 31, 2024

(51) Int. Cl. H10D 30/67; H01L 21/02; H10D 30/01; H10D 62/40; H10D 62/80

(52) U.S. Cl. CPC H10D 30/6757; H10D 30/031; H10D 30/6755; H10D 62/405; H10P 14/22; H10P 14/3466; H10D 62/875; H10P 14/3434

(57) ABSTRACT

A method of fabricating a semiconductor device, includes steps of forming a gate electrode on a dielectric layer; forming an insulator layer on the gate electrode; forming a channel layer to cover a portion of the insulator layer, wherein the channel layer comprises a first element from a group 12 and a second elements from a group 13 of the periodic table, and a composition of the first element is graded across at least a portion of a thickness of the channel layer; and forming a source electrode and a drain electrode on the channel layer, wherein the source electrode and the drain electrode are separated from each other.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the size of the smallest component (or line) that can be created using a fabrication process) has decreased.

Various active or passive electronic components can be formed on a semiconductor IC. For example, transformers, inductors, capacitors, etc. may be formed on a semiconductor IC. However, conventional electronic components formed on an IC may incur shortcomings such as excess space consumption, poor device performance, inadequate shielding, and high fabrication costs.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional view of a semiconductor device assembly, in accordance with some embodiments of the present disclosure.

FIG. 2 is a cross-sectional view of a channel layer, in accordance with some embodiments of the present disclosure.

FIG. 3 is a schematic cross-sectional view of an integrated circuit, in accordance with some embodiments of the present disclosure.

FIG. 4 is a flowchart of a method of manufacturing a semiconductor device, in accordance with some embodiments of the present disclosure.

FIGS. 5 to 12 are cross-sectional views of intermediate stages of the method of manufacturing a semiconductor photonic device, in accordance with some embodiments of the present disclosure.

FIG. 13 is a schematic diagram of an apparatus for the formation of a channel layer, in accordance with some embodiments of the present disclosure.

FIG. 14 is a schematic diagram of a deposition tool for the formation of a base film, a transition film, and a capping film of a channel layer, in accordance with some embodiments of the present disclosure.

FIG. 15 is a flowchart of a method of manufacturing a semiconductor device and an interconnect structure, in accordance with some embodiments of the present disclosure.

FIGS. 16 to 21 are cross-sectional views of intermediate stages of the method of manufacturing a semiconductor photonic device and the interconnect structure, in accordance with some embodiments of the present disclosure.

FIG. 22 is an x-ray diffraction (XRD) profile of a channel layer, in accordance with some embodiments of the present disclosure.

FIG. 23 shows reliability data for a semiconductor device provided with a channel layer structured by c-axis aligned crystal and a semiconductor device provided with a channel layer having an amorphous structure.

FIG. 24 illustrates a change in voltage depending on a concentration of zinc and a change in depending on a concentration of indium, in accordance with some embodiments of the preset disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

The present disclosure is directed to a thin-film transistor and a method of manufacturing the same. The transistor includes a channel layer structured by c-axis aligned crystal (CAAC). The channel layer includes at least two sublayers disposed over a substrate of an integrated circuit. The substrate may include various microelectronic elements and various conductive features, wherein the microelectronic elements and the transistor are interconnected via the conductive features to form various electrical circuits of the integrated circuit. The at least two sublayers includes a first sublayer and a second sublayer that contain different composition ratios of indium, gallium, zinc, and oxygen. The first sublayer is between the substrate and the second sublayer and may have a greater composition of zinc for CAAC structure growth. The second sublayer may have a graded composition of zinc with a concentration of zinc that gradually decreases with distance away from the first sublayer. Further, the channel layer includes carriers having a lower concentration in the second sublayer than in the first sublayer. Grading the zinc composition in the second sublayer may lower the carrier concentration of the channel layer to thereby increase a threshold voltage (Vt) of the transistor (e.g., move the threshold voltage toward a more positive direction).

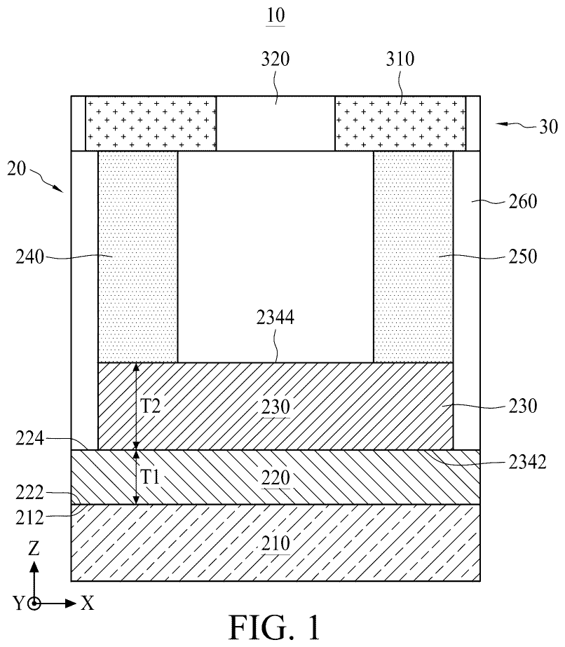

FIG. 1 is a schematic cross-sectional view of a semiconductor device assembly 10, in accordance with some embodiments of the present disclosure. Referring to FIG. 1, the semiconductor device assembly 10 includes a semiconductor device 20, e.g., a thin film transistor, and an interconnect structure 30 over the semiconductor device 20. In some embodiments, the semiconductor device 20 includes a gate electrode 210, an insulator layer 220, a channel layer 230, a source electrode 240, and a drain electrodes 250, wherein the insulator layer 220 is between the gate electrode 210 and the channel layer 230, and the source electrode 240 and the drain electrode 250 are disposed on the channel layer 230.

In some embodiments, the gate electrode 210 includes a metallic material or a metal compound. The metallic material may include, for example, but not limited thereto, copper (Cu), aluminum (Al), tungsten (W), silver (Ag), gold (Au), nickel (Ni), other suitable materials, alloys thereof, or combinations thereof. The metal compound may include, for example, but not limited to, titanium nitride (TiN), tantalum nitride (TaN), metal silicide, other suitable materials, or combinations thereof. Other material suitable for forming the gate electrode 210 are within the scope of the present disclosure. The gate electrode 210 may be disposed by, for example, physical vapor deposition (PVD), chemical vapor deposition (CVD), sputtering, plating, combination thereof, or other suitable techniques.

The insulator layer 220 is disposed on the gate electrode 210. The insulator layer 220 may cover an entirety of an upper surface 212 of the gate electrode 210. The insulator layer 220 includes a lower surface 222 and an upper surface 224 opposite to the lower surface 222, wherein the lower surface 222 of the insulator layer 220 is in direct contact with the upper surface 212 of the gate electrode 210. The insulator layer 220 may function as a gate dielectric of the semiconductor device 20. The insulator layer 220 may include an oxide (e.g., silicon dioxide (SiO₂), aluminum oxide (Al₂O₃), or hafnium oxide (HfO₂)), a high-dielectric-constant (high-k) dielectric material, other dielectric materials, or a combination thereof. In some embodiments, the insulator layer 220 may include one or more layers, wherein each layer is made using one or more of the dielectric materials mentioned above. The insulator layer 220 may have a thickness T1 between about 20 angstroms and about 100 angstroms. The insulator layer 220 may be formed by, for example, sputtering, CVD, PVD, atomic layer deposition (ALD), plasma-enhanced ALD, molecular beam epitaxy (MBE), a combination thereof, or other suitable techniques.

The channel layer 230 is disposed on the insulator layer 220. The channel layer 230 may cover a portion of the upper surface 224 of the insulator layer 220, and expose another portion of the upper surface 224 of the insulator layer 220. In an example, the channel layer 230 extends laterally on the upper surface 224 of the insulator layer 220. The insulator layer 220 separates the channel layer 230 from the gate electrode 210. In some embodiments, the channel layer 230 has a thickness T2 of about 40 angstroms to about 500 angstroms. For example, the channel layer 230 may have the thickness T2 of about 50 angstroms to 100 angstroms.

The channel layer 230 includes a multicomponent oxide material. In some embodiments, the channel layer 230 includes elements from group 12 and group 13 of the periodic table of elements (hereinafter referred to as the periodic table). The channel layer 230 may include an element from group 12 and two elements from group 13 of the periodic table. For example, the channel layer 230 may be a three-component oxide that includes zinc (Zn) from group 12 of the periodic table and gallium (Ga) and indium (In) from group 13 of the periodic table. In some embodiments, the channel layer 230 includes indium-gallium-zinc oxide (InGaZnO or IGZO). In alternative embodiments, the channel layer 230 includes cadmium-gallium-indium oxide, indium-aluminum-zinc oxide, or aluminum-gallium-zinc oxide. The channel layer 230 may be formed on the insulator layer 220 using sputter deposition.

The channel layer 230 may have crystallinity. In some embodiments, the channel layer 230 is in a non-single-crystal state. The channel layer 230 may exhibit a c-axis orientation. For example, the channel layer 230 may be structured by c-axis aligned crystal (CAAC). The CAAC may have atoms arranged in a triangular, hexagonal, equilateral triangular, or regular hexagonal shape when seen from a direction perpendicular to an a-b plane, and have a phase in which metal atoms are arranged in layers in the c-axis direction or a phase in which metal atoms or oxygen atoms are arranged in the c-axis direction. The channel layer 230 is not a single crystal and, in addition, is not composed of an amorphous component.

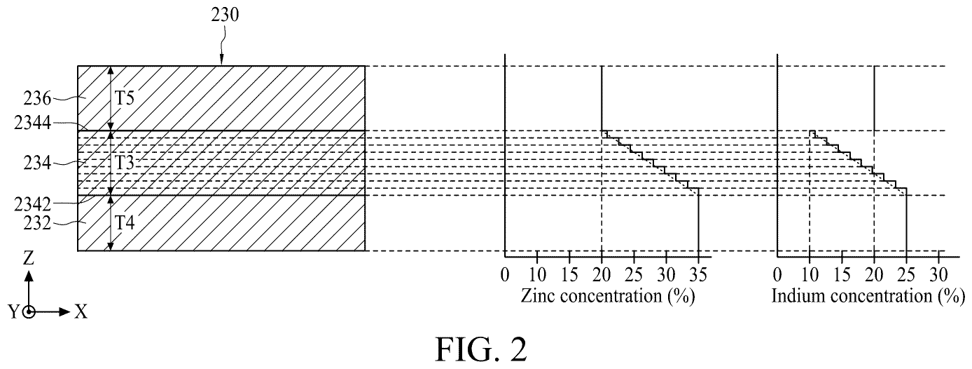

FIG. 2 is a cross-sectional view of the channel layer 230 juxtaposed to show concentration profiles of zinc and indium, in accordance with some embodiments of the present disclosure. Referring to FIGS. 1 and 2, in some embodiments, the channel layer 230 includes a base film 232, a transition film 234, and a capping film 236 sequentially stacked on the insulator layer 220. The base film 232 may contact the insulator layer 220, and the transition film 234 is disposed between the base film 232 and the capping film 236. The base film 232, the transition film 234, and the capping film 236 may contain different composition rations of indium, gallium, zinc, and oxygen. In some embodiments, the base film 232 has a concentration of zinc greater than a concentration of zinc in the capping film 236. For example, the base film 232 may have a concentration of zinc equal to or greater than about 35% (atomic percentage), and the capping film 236 may have a concentration of zinc equal to or less than more than about 20%.

The transition film 234 between the base film 232 and the capping film 236 of different composition has a composition transitions from the base film 232 to the capping film 236. In some embodiments, the transition film 234 has a graded composition in a thickness direction, i.e., the Z direction. The composition may be graded by varying a concentration of at least one element, such as zinc, throughout the thickness of the transition film 234. The transition film 234 is vertically graded. The graded composition(s) is included to, for example, reduce a carrier concentration in the channel layer 230.

For example, the transition film 234 has a gradient zinc concentration profile that decreases at positions of increasing distance from the base film 232. The concentration of zinc in the transition film 234 may gradually decrease along a direction from the base film 232 to the capping film 236. The transition film 234 may have a concentration of zinc ranging from about 20% to about 35%. For example, a region of the transition film 234 adjacent to the base film 232 may have a content of zinc of about 35%. The zinc content of the transition film 234 may gradually decrease to about 20% in a region of the transition film 234 adjacent to the capping film 236. The transition film 234 may have a lower surface 2342 interfacing with the base film 232 and an upper surface 2344 opposite to the lower surface 2342 and interfacing with the capping film 26. In some embodiments, the transition film 234 has a varying concentration of zinc between the lower surface 2342 and the upper surface 2344. The varying concentration may have a high concentration of zinc, e.g., 35%, at the lower surface 2342 of the transition film 234 and have a reduced concentration of zinc, e.g., 20%, at the upper surface 2344 of the transition film 234.

The transition film 234 may have a varying concentration of indium for further reducing the carrier concentration in the channel layer 230. The varying concentration may include a high concentration of indium at the lower surface 2342 of the transition film 234 and a reduced concentration of indium at the upper surface 2344 of the transition film 234. The transition film 234 may have a concentration of indium ranging from about 10% to about 25%. In some embodiments, the concentration of indium in the transition film 232 gradually decreases along the direction from the lower surface 2342 to the upper surface 2344. For example, the transition film 234 may have a concentration of indium of about 25% at or proximal to the lower surface 2342. The indium content in the transition film 234 gradually decreases to about 10% at or proximal to the upper surface 2344.

The compositional grading in the transition layer 234 may be accomplished, for example, by either linear grading or discrete-stepped grading. The concentration of the zinc/indium in the transition layer 234 may continuously decrease or may decrease in stepped decrements. A concentration of gallium remains constant throughout the transition layer 234. A ratio of zinc to gallium proximal to the lower surface 2342 of the transition film 234 is greater than a ratio of zinc to gallium proximal to the upper surface 2344 of the transition film 234. Further, a ratio of indium to gallium proximal to the lower surface 2342 of the transition film 234 is greater than a ratio of indium to gallium proximal to the upper surface of the transition film 234. A concentration of oxygen may remain constant throughout the transition layer 234. The present disclosure, however, is not limited thereto. The transition film 234 may have a thickness T3 ranging from about 10 angstroms to about 30 angstroms.

The base film 232 may have a thickness T4 equal to or greater than about 15 angstroms. The base film 232 serves as a seed layer for the CAAC structure growth and thus has a function of increasing crystallinity of the CAAC. The concentration of zinc in the base film 232 being less than about 35% and the thickness T4 being less than about 15 angstroms may cause the channel layer 230 to fail to structure in CAAC.

The concentration of zinc across the base film 232 may be equal to or greater than about 35%. In some embodiments, the base film 232 is compositionally uniform. The base film 232 may have constant composition across the entire thickness. For example, the zinc content is present in a substantially uniform concentration along an entire thickness of the base film 232, such as the concentration shown in FIG. 2. In alternative embodiments, the base film 232 is compositionally graded across the Z direction. A concentration of zinc in the base film 232 may be graded continuously, discontinuously, across the entire thickness, or across only a portion of the thickness. For example, the base film 232 may have a gradient zinc concentration profile that increases at positions of increasing distance from the transition film 234.

The concentration of the zinc in the capping film 236 may be equal to or less than about 20%. The reduced concentration of zinc may reduce carrier concentration in the capping film 236. Further, the capping film 236 may have a thickness T5 from about 10 angstroms to about 30 angstroms. The concentration of indium in the capping film 236 may be equal to or less than 20%. In some embodiments, the composition is uniform throughout the capping film 236. For example, as shown in FIG. 2, the zinc content is present in a substantially uniform concentration along an entire thickness of the capping film 236, and the indium content is also present in a substantially uniform concentration along an entire thickness of the capping film 232. However, the disclosure is not limited thereto. The composition may be graded across at least a portion of the thickness of the capping film 236. For example, the capping film 236 may have a gradient zinc concentration profile that decreases as the positions of increasing distance from the transition film 234.

Generally, zinc has a carrier mobility greater than a carrier mobility of gallium. Composition grading of the transition film 234 by grading the zinc (and indium) and forming the capping film 236 with a lower zinc concentration as compared to the base film 232 may reduce the carrier concentration of the channel layer 230. Accordingly, an electron mobility of the channel layer 230 is decreased, thereby increasing a threshold voltage of the semiconductor device. For example, the channel layer 230 of the present disclosure may move the threshold voltage of the semiconductor device 20 toward a more positive direction.

The source electrode 240 and the drain electrode 250 are in direct contact with the capping film 236 of the channel layer 230. In some embodiments, the source and drain electrodes 240 and 250 are disposed on peripheral portions of the channel layer 230 and laterally spaced from each other by a dielectric layer 260. The source electrode 240 contacts a first end portion of the channel layer 230, and the drain electrode 250 contacts a second end portion of the channel layer 230. The source electrode 240 and the drain electrode 250 may include metallic material such as copper, aluminum, tungsten, titanium, tantalum, cobalt (Co), ruthenium (Ru), molybdenum (Mo), alloys thereof, or combinations thereof. Other suitable materials within the contemplated scope of disclosure may also be used. In some embodiments, the dielectric layer 260 may further cover the insulator layer 220 and laterally surround the channel layer 230. The dielectric layer 260 may include oxide or suitable low-k dielectric material.

The interconnect structure 30 is coupled to the semiconductor device 20. The interconnect structure 30 may include various conductive features 310 and a dielectric layer 320 laterally surrounding the conductive features 310. In some embodiment, the conductive features 310 contact the source and drain electrodes 240 and 250 to electrically connect to the semiconductor device 20. The interconnect structure 30 may be used to connect to an external circuit (not shown) outside the semiconductor device assembly 10. The conductive features 310 may be formed of copper, tungsten, aluminum, combinations thereof, or the like. The conductive features 310 may be formed by a single damascene operation or a dual damascene operation. The dielectric layer 320 may include an oxide (such as silicon oxide), a nitride (such as silicon nitride), an oxynitride (such as silicon oxynitride), a carbide (such as silicon carbide), an oxycarbide (such as silicon oxycarbide), a low-dielectric-constant (low-k) dielectric material, an ultra-low-k dielectric material, other dielectric materials, or a combination thereof.

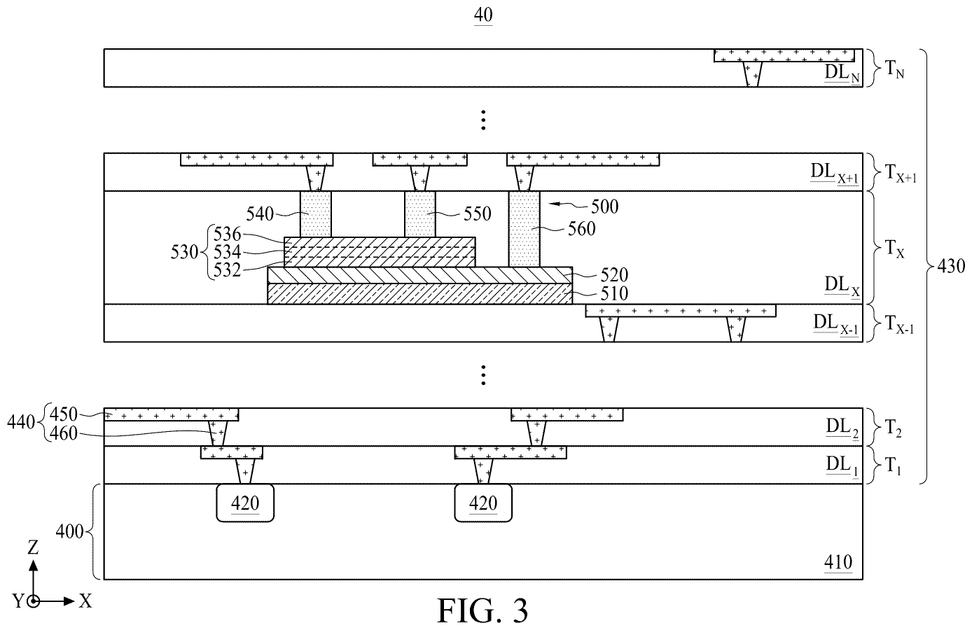

FIG. 3 is a schematic cross-sectional view of an integrated circuit 40, in accordance with some embodiments of the present disclosure. Referring to FIG. 3, in some embodiments, the integrated circuit 40 includes a core layer 400 and an interconnect layer 430 over the core layer 400. The core layer 400 may include a substrate 410 and various microelectronic elements 420 (such as transistors, capacitors, resistors, diodes, inductor, and the like) disposed in and/or on the substrate 410. In some embodiments, the substrate 410 includes semiconductive material such as silicon, germanium, gallium, or the like. The microelectronic elements 420 may be formed in and/or on the substrate 410 in a front-end-of-line (FEOL) stage.

The interconnect layer 430 includes an interconnect stack. The interconnect stack includes a plurality of conductive features 440, at least one semiconductor device 500, and one or more dielectric layers, such as DL₁ to DL_{N}, where N is an integer. The conductive features 440 may be at least between the microelectronic elements 420 and the semiconductor device 500, and electrical signals may be routed to and/or from the microelectronic elements 420 and the semiconductor device 500 through the conductive features 440. The microelectronic elements 420 and the semiconductor device 500 are interconnected via the conductive features 440 to form various electrical circuits of the integrated circuit 30.

In some embodiments, the semiconductor device 500 and the conductive features 440 are disposed at different layers in the interconnect stack. For example, as shown in FIG. 3, the semiconductor device 500 is located at the dielectric layer DL_{X} the interconnect stack, and the conductive features 440 are located at dielectric layers DL₁ to DL_{X-1} and dielectric layers DL_{X+1} to DL_{N}, wherein X is an integer less than N. In the present disclosure, however, the semiconductor devices 500 and some of the conductive features 420 may be disposed in a same dielectric layer the interconnect stack.

In some embodiments, the conductive features 440 include alternating conductive lines 450 and conductive vias 460. In some embodiments, the conductive lines 450 extend horizontally in the dielectric layers DL₁-DL_{N}, and the conductive vias 460 extend vertically to provide electrical connections between the conductive lines 450 in different dielectric layer DL₁-DL_{N}. For example, a conductive via 460 allows a conductive line 450 in the dielectric layer DL₁ to be electrically connected to another conductive line 450 in the dielectric layer DL₂. The conductive lines 450, the conductive vias 460, and the semiconductor devices 500 may be formed in dielectric layers DL₁-DL_{N}. The dielectric layers DL₁-DL_{N} may each include an oxide, a nitride, an oxynitride, a carbide, an oxycarbide, a low-k dielectric material, an ultra-low-k dielectric material, other dielectric materials, or a combination thereof. The interconnect layer 430 that includes the conductive features 440, the semiconductor device 500, and the dielectric layers DL₁-DL_{N} may be formed over the substrate 320 and the microelectronic elements 330 in a back-end-of-line (BEOL) stage. Therefore, the fabrication of the semiconductor device 500 may be compatible with the BEOL operation of the integrated circuit 30, thereby simplifying operation steps and efficiently improving the integration density.

The semiconductor device 500 includes a gate electrode 510, an insulator layer 520, a channel layer 530, a source electrode 540, a drain electrode 550, and a gate contact 560. The gate electrode 510 is disposed on the dielectric layer DL_{X}. The insulator layer 520 and the channel layer 530 are sequentially stacked on the gate electrode 510. The source electrode 540 and the drain electrode 550 are disposed on the channel layer 530. Further, the source electrode 540 is separated from the drain electrode 550 by the dielectric layer DL_{X}. The gate contact 560 penetrates through the insulator layer 520 and contacts the gate electrode 510. The dielectric layer DL_{X} laterally surrounds the gate electrode 510, the insulator layer 520, the channel layer 530, the source electrode 540, the drain electrode 550, and the gate contact 560.

The insulator layer 520 is disposed on the gate electrode 510 and functions as a gate dielectric. The channel layer 530 overlaps and contacts a portion of the insulator layer 520. The channel layer 530 is made of materials that can be formed by deposition at temperatures below 450 degrees Celsius, which is compatible with the BEOL stage. For example, the channel layer 530 includes IGZO. The channel layer 530 may be structured by CAAC. Thus, the reliability of the semiconductor device 500 in the integrated circuit 30 is increased.

The channel layer 530 includes a base film 532, a transition film 534, and a capping film 536 that contains indium, gallium, zinc, and oxygen. The transition film 534 may be between the base film 532 and the capping film 536 and compositionally graded across the Z-direction. In some embodiments, the transition film 534 has a gradient zinc profile, where a concentration of the zinc ranges from about 20% to about 35%. For example, the transition film 534 may have a zinc concentration of about 35% at a first interface with the base film 532. The concentration of the zinc gradually decreases from the first interface to a second interface with the capping film 536. The transition film 534 may have a zinc concentration of about 20% at the second interface with the capping film 536.

In some embodiments, the transition film 534 has a gradient indium profile, where a concentration of the indium ranges from about 10% to about 25%. For example, the transition film 534 may have an indium concentration of about 25% at the first interface with the base film 532. The concentration of indium gradually decreases from the first interface to the second interface with the capping film 536. The transition film 534 may have an indium concentration of about 10% at the second interface with the capping film 536.

In some embodiments, the concentration of the zinc in the base film 532 is greater than a concentration of the zinc in the capping film 536. For example, the concentration of the zinc in the base film 532 is equal to or greater than about 35%, and the concentration of the zinc in the capping film 536 is equal to or less than about 20%. Further, a concentration of indium in the capping film 536 is equal to or less than about 20%. The zinc-rich base film 532 serves as a seed layer for CAAC structure growth. The semiconductor device 500 has a threshold voltage, which is the voltage at which the semiconductor device 500 is turned on or off. The concentration of zinc in the channel layer 530 may define the threshold voltage with a higher content in a more negative threshold. This is due to the high conductivity (i.e., many carriers) of the zinc. A semiconductor device, containing the channel layer 530 structured by CAAC and having the concentration of zinc of about 35% throughout its thickness may result in a lower threshold voltage (i.e., a more negative threshold voltage). The semiconductor device including the zinc-rich channel layer may have a relatively large on-current as when a positive threshold voltage is applied. In short, a semiconductor device with excessive zinc content does not operate as a transistor. Composition grading of zinc in the transition film 534 and a reduced composition of zinc in the capping film 536 may reduce a carrier concentration in the channel layer 530, thereby increasing the threshold voltage (e.g., moving the threshold voltage toward a more position direction).

The source electrode 540 and the drain electrode 550 are in direct contact with the capping film 536. The gate contact 560 is separated from the source/drain electrode 530/540 and the channel layer 530 by the dielectric layer DL_{X}. The insulator layer 520 may laterally surround the bottom portion of the gate contacts 560. In some embodiments, the gate electrode 510, the source electrode 540, the drain electrode 550, and the gate contact 560 are made of materials same as materials of the conductive features 440.

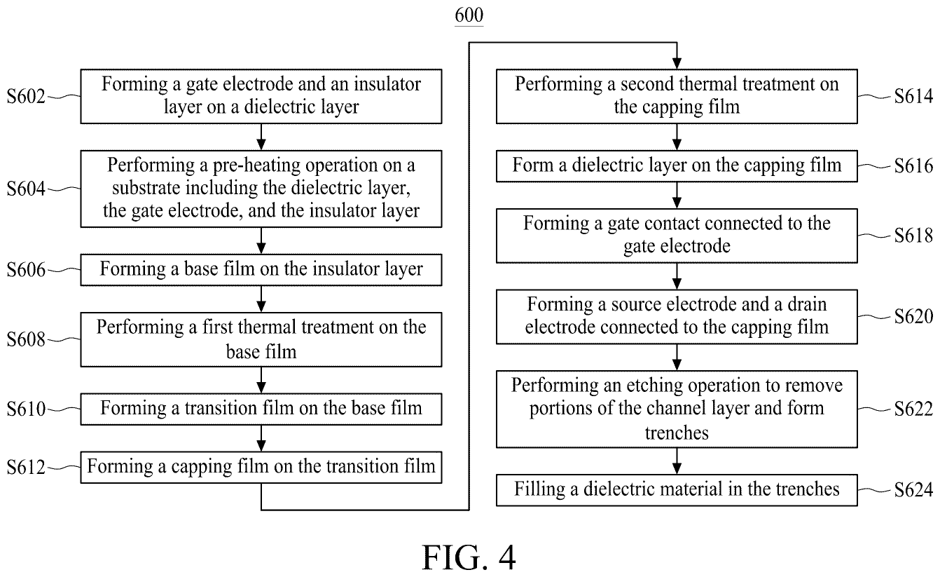

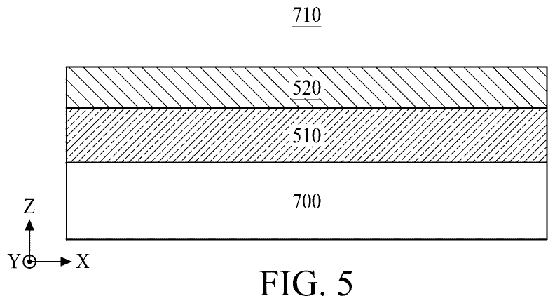

FIG. 4 is a flowchart of a method 600 of manufacturing a semiconductor device 500, in accordance with some embodiments of the present disclosure. FIGS. 5 to 12 are cross-sectional views of intermediate stages of the method 600 of manufacturing the semiconductor device 500, in accordance with some embodiments of the present disclosure. In the following description, the manufacturing stages shown in FIGS. 5 to 12 are discussed with reference to process steps shown in FIG. 4. It should be understood that additional steps can be provided before, during, and after the steps shown in FIG. 4, and some of the steps described below can be replaced or eliminated, for additional embodiments of the method 600. The order of the steps may be changed.

Referring to FIG. 5, in some embodiments, a gate electrode 510 and an insulator layer 520 are sequentially formed on a dielectric layer 700 in accordance with step S602 in FIG. 4. The dielectric layer 700 may be disposed over a bulk substrate. The bulk substrate is a semiconductive substrate. In some embodiments, the bulk substrate includes semiconductive material such as silicon, germanium, gallium, arsenic, or a combination thereof. In some embodiments, the bulk substrate includes a material such as ceramic, glass, polymer or the like. In some embodiments, the bulk substrate includes an organic material. In some embodiments, the bulk substrate has a quadrilateral, rectangular, square, polygonal, or any other suitable shape.

Various microelectronic elements may be disposed in and/or on the bulk substrate and an interconnect structure may be between the bulk substrate and the dielectric layer and between the microelectronic elements and the dielectric layer 700. The microelectronic elements may be formed in and/or on the bulk substrate through various operations including deposition, etching, implantation, photolithography, annealing, and/or other suitable operations. The interconnect structure may include various conductive features coupled to the microelectronic elements and one or more dielectric layers laterally surround the conductive features. The conductive features may be formed in the dielectric layers by single damascene operations or dual damascene operations. The damascene operation may include performing lithography and etching operations to form a plurality of trenches in one of the dielectric layers, filling the trenches with a metallic material, and performing a planarization to remove excess metallic material to thereby form the conductive features.

The gate electrode 510 is formed on the dielectric layer 700. The gate electrode 510 may include a metallic material (such as copper, aluminum, silver, gold, or nickel) or a metal compound (such as titanium nitride or tantalum nitride). The gate electrode 510 may be disposed by, for example, PVD, CVD, sputtering, plating, a combination thereof, or other suitable techniques. The insulator layer 520 is formed on the gate electrode 510. The insulator layer 520 may include silicon dioxide, aluminum oxide, silicon dioxide, aluminum oxide, hafnium oxide, or the like, and may be deposited by any suitable method, such as CVD, PVD, ALD, MBE, the like, or a combination thereof.

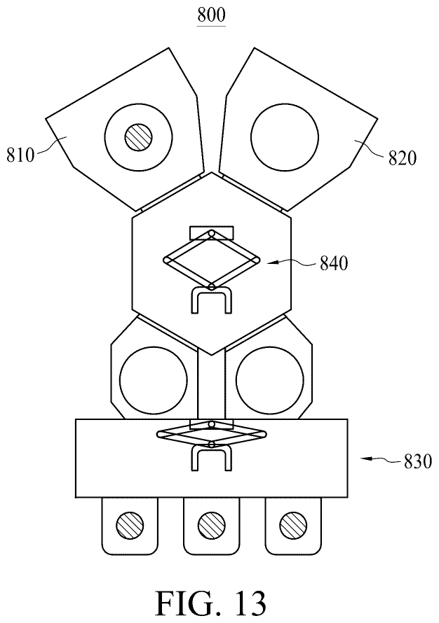

The dielectric layer 700, the gate electrode 510, and the insulator layer 520 are collectively referred to as a substrate 710 hereinafter. After the formation of the insulator layer 520, the substrate 710 is transported into an apparatus 800 as shown in FIG. 13 for the formation of a channel layer 530. Referring to FIG. 13, the apparatus 800 is installed in a cleanroom (not separately shown) and includes a deposition chamber 810 and a thermal chamber 820. Air controlled to a predetermined temperature circulates in the cleanroom to keep an internal temperature of the cleanroom approximately constant or within a predetermined range. The apparatus 800 may be connected to a load-lock chamber 830, which is used when loading and unloading a substrate (such as the substrate 710) into and from the apparatus 800. The apparatus 800 may further includes a transport robot 840. The deposition chamber 810, the thermal chamber 820, and the load-lock chamber 830 are arranged around the transport robot 840 so that each is able to perform delivery and receipt of the substrate 710 with the transport robot 840.

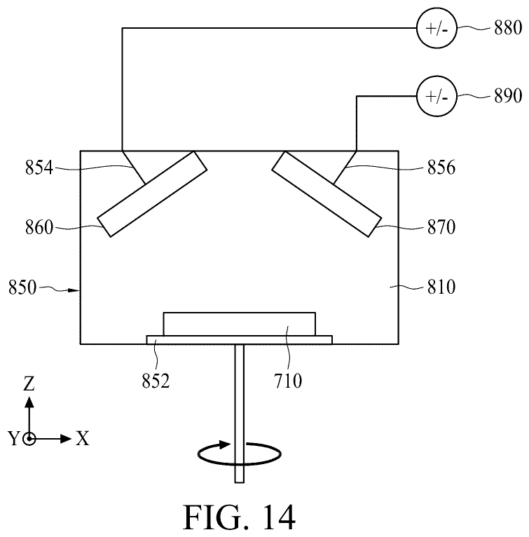

FIG. 14 is a schematic diagram of a deposition tool 850 in accordance with some embodiments of the present disclosure. Referring to FIG. 14, the deposition tool 850 is positioned in the deposition chamber 810 and includes a substrate supporter 852 and a plurality of target holders 854 and 856. The substrate supporter 852 may be a pedestal for supporting the substrate 710 to be deposited. In some embodiments, the substrate supporter 852 is temperature-controlled. Inside the deposition tool 850, a first target 860 and a second target 870 are held on the target holders 854 and 856, respectively. The substrate supporter 852 holds a deposited surface of the substrate 710 facing upward at a predetermined position to receive sputtering particles emitted from the first and second targets 860 and 870 arrived at. The substrate supporter 852 is connected to a rotating mechanism (not shown) and is configured so as to enable the deposited surface of the substrate 710 to rotate in a horizontal plane during deposition.

The first target 860 and the second target 870 are provided above the deposited surface of the substrate 710 and are oriented at an angle with respect to the deposited surface of the substrate 710. Power supplies 880 and 890, which apply electrical power for sputter discharge, are connected to the target holders 854 and 856, respectively. The power supplies 880 and 890 may be direct current (DC) power supplies. Sputtering is carried out as a result of formation of plasma when electrical power is applied to the first target 860 from the power supply 880 or to the second target 870 from the power supply 890. The target holders 854 and 856 may be made of metal and serve as electrodes when electrical power is applied thereto. In addition, the target holders 854 and 856 are insulated from the deposition chamber 810 by insulators.

The first target 860 and the second target 870 are composed of raw materials of the channel layer 530 formed on the substrate 710. In some embodiments, the first target 860 and the second target 870 are both IGZO targets but with different concentrations of zinc. For example, the first target 870 may have a concentration of zinc of about 50% or more, and the second target 880 may have a concentration of zinc of about 25% or less.

Referring to FIGS. 4 and 5, the method 600 proceeds to step S604, in which a pre-heat operation is performed on the substrate 710. In some embodiments, the pre-heat operation is performed in the thermal chamber 820 shown in FIG. 13.The thermal chamber 820 includes a heater member (not shown), which is in some embodiments is a lamp heater. The lamp heater may include an infrared lamp. The pre-heat operation is performed to heat at least portions of the substrate 710 to a pre-heat temperature below melting points of the dielectric layer 700, the gate electrode 510, and the insulator layer 520. In some embodiments, the pre-heat operation is performed at a pre-heat temperature in a range from about 300 degrees Celsius to about 400 degrees Celsius. For example, the pre-heat operation is at the pre-heat temperature of about 350 degrees Celsius. The substrate 710 is pre-heated for the formation of the channel layer 530 with a desired crystallinity.

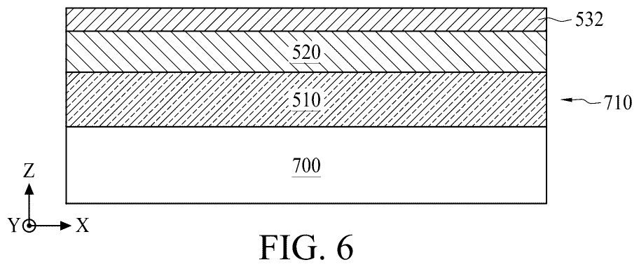

Referring to FIGS. 6 and 13, a base film 532 is formed on the insulator layer 520 in accordance with step S606 in FIG. 4. The base film 532 is deposited by a PVD operation. The PVD operation is performed in the deposition tool 850. The PVD operation for the formation of the base film 532 may be carried out by switching on the power supply 880 and switching off the power supply 890. Accordingly, a DC power is applied to the target holder 854 to cause constituent elements of the first target 860 to scatter. The constituent elements scatter in the deposition chamber 810 with some coming to rest on the insulator layer 520. The constituent elements of the first target 860 may be laminated on the insulator layer 520 to form the base film 532. The base film 532 may have a concentration of zinc equal to or greater than about 35%. In some embodiments, during the formation of the base film 532, the substrate 710 is maintained at the pre-heat temperature to facilitate the crystallization of the base film 532. In some embodiments, the base film 532 is crystalline when initially formed. The first deposition is performed until the base film 532 has a thickness of at least about 15 angstroms. Greater thicknesses of the base film 532 provide better crystallinity of the channel layer 530.

After the formation of the base film 532, the substrate 710 with the base film 532 is transported to the thermal chamber 820 shown in FIG. 13. Subsequently, a first thermal treatment is performed on the base film 532 and the substrate 710 in accordance with step S608 in FIG. 4. The first thermal treatment is performed at least on the base film 532 to a predetermined temperature at or above a crystallization point of IGZO. The predetermined temperature may be lower than a melting temperature of IGZO. The predetermined temperature is about 200 degrees Celsius. The first thermal treatment may create a more crystalline structure of the base film 532. The first thermal treatment may be performed in a vacuum environment such as a vacuumed chamber.

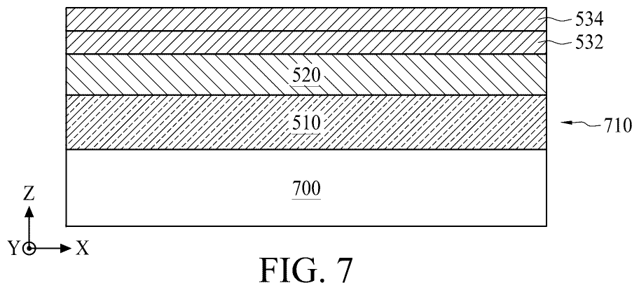

After the first thermal treatment is completed, the substrate 710 with the base film 532 is transported to the deposition chamber 810 shown in FIG. 13. Subsequently, referring to FIG. 7, a transition film 534 is formed on the base film 532 in accordance with step S610 in FIG. 4. The transition film 534 may be formed on the base film 532 by performing a cyclic operation of alternating sequence of deposition and heating. In some embodiments, the cyclic operation includes one or more cycles of deposition and heating. For example, the deposition and heating may be repeated from one to ten cycles.

The deposition may be performed in the deposition chamber 810 in FIG. 13. The deposition may be carried out by switching on both of the power supplies 880 and 890. Accordingly, DC powers are applied to the target holders 854 and 856 to cause constituent elements of the first and second targets 860 and 870 to scatter. The constituent elements scatter in the deposition chamber 810 with some coming to rest on the base film 532. At a beginning of the cyclic operation, the DC power applied to the first target 860 may be greater than the DC power applied to the second target 870, so that a layer with a higher zinc concentration is initially laminated on the base film 532. The DC power applied to the first target 860 may gradually decrease and the DC power applied to the second target 870 may gradually increase as cycle number increases, to thereby forming the transition film 534 having zinc with graded composition. In some embodiments, the transition film 534 has a gradient zinc concentration profile that decreases at positions of increasing distance from the base 532. The transition film 534 may have a concentration of zinc ranging from about 20% to about 35%. For example, a region of the transition film 534 adjacent to the base film 532 may have a content of zinc of about 35%. The zinc content of the transition film 534 may gradually decrease to about 20%.

The heating of the formed layer on the base film 532 may be performed in the thermal chamber 820. The heating step is perform to raise a temperature of the formed layer on the base film 532. The heating step may create a more crystalline structure of the formed layer on the base film 532. The heating step is performed to at least on the formed layer on the base film 532 to a predetermined temperature at or above a crystallization point of IGZO. The heating step is performed to maintain a temperature of the formed layer on the base film 532 of about 200 degrees Celsius.

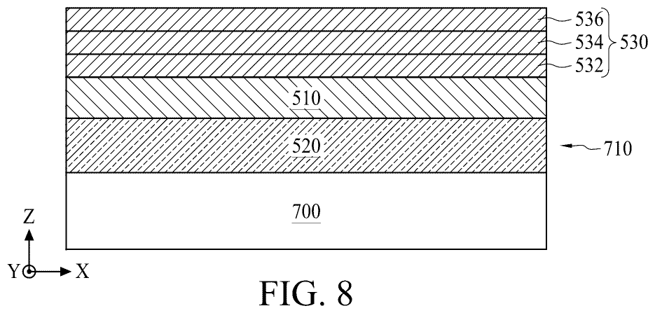

Subsequently, referring to FIG. 8, a capping film 536 is formed on the transition film 534 in accordance with step S612 in FIG. 4. The capping film 536 may be formed using the deposition chamber 810 shown in FIG. 13. The capping film 536 is deposited by a PVD operation. The PVD operation may be performed in the deposition tool 850 in FIG. 14. The PVD operation for the formation of the capping film 536 may be carried out by switching off the power supply 880 and switching on the power supply 890. Accordingly, DC power is applied to the target holder 856 to cause constituent elements of the second target 870 to scatter. The constituent elements scatter in the deposition chamber 810 with some coming to rest on the transition film 534. The constituent elements of the second target 870 may be laminated on the transition layer 534 to form the capping film 536. The base film 532, the transition film 534, and the capping film 536 are collectively referred to as the channel layer 530. The capping film 536 may have a concentration of zinc not more than about 20%.

After the formation of the capping film 536, the substrate 710 with the channel layer 530 is transported to the thermal chamber 820 shown in FIG. 13. Subsequently, the substrate 710 and the channel layer 530 are subjected to a second thermal treatment in accordance with step S614 in FIG. 4. The second thermal treatment creates a more crystalline structure of the capping film 536. The second thermal treatment is performed to raise a temperature of the capping film 536 of about 200 degrees Celsius.

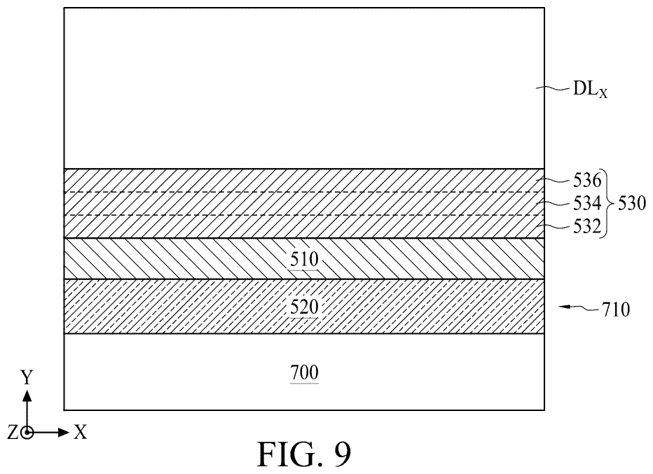

Referring to FIG. 9, a dielectric layer DL_{X} is formed on the capping film 536 in accordance with step S616 in FIG. 4. The dielectric layer DL_{X} may cover an entirety of an upper surface of the capping film 536. The dielectric layer DL_{X} may be deposited on the capping film 536 by any suitable method, such as CVD, plasma enhanced CVD (PECVD), a spin-on operation, a combination thereof, or the like.

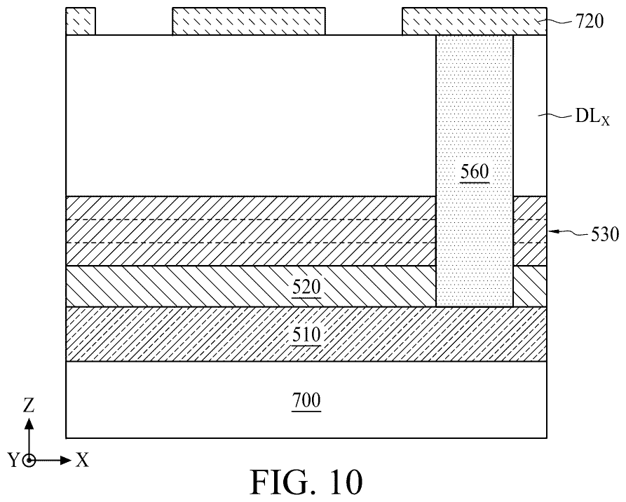

Referring to FIG. 10, a gate contact 560 is formed to connect to the gate electrode 510 in accordance with step S618 in FIG. 4. The gate contact 560 may be formed to penetrate through the dielectric layer DL_{X}, the channel layer 530, and the insulator layer 520 by photolithography and etching operations to form a first via trench that exposes a portion of the gate electrode 510, and then filling the first via trench with a conductive material by deposition, sputtering, plating, or combinations thereof. The etching operations may include a wet etch, a dry etch, a combination thereof (e.g., reactive ion etch (RIE)), or the like. Excess portions of the conductive material are removed from a top surface of the dielectric layer DL_{X} using a CMP operation, an etch operation, or combinations thereof to form the gate contact 560.

After the formation of the gate contact 560, a patterned mask layer 720 is formed on the gate contact 560 and portions of the dielectric layer DL_{X}. The formation of the patterned mask layer 720 may include forming a mask layer and a blanket photoresist layer on the gate contact 560 and the dielectric layer DL_{X} and patterning the blanket photoresist layer. Patterns of the photoresist layer is then transferred to the mask layer, thereby forming the patterned mask layer 720.

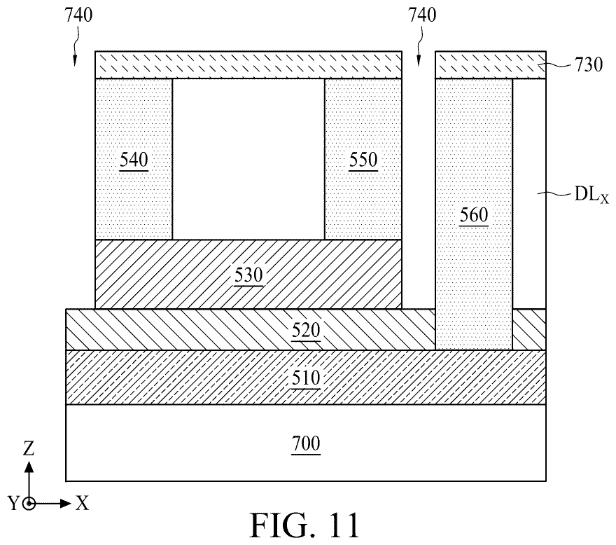

Referring to FIGS. 10 and 11, a source electrode 540 and a drain electrode 550 are formed to connect to the capping film 536 in accordance with step S620 in FIG. 4. The source electrode 540 and the drain electrode 550 may be formed to penetrate through the dielectric layer DL_{X} by etching operations to form second via trenches that expose portions of the channel layer 530, using the patterned mask layer 720 as an etch mask. Subsequently, by deposition, sputtering, plating, or combinations thereof the second via trenches are filled with a conductive material. The etching operations may include a wet etch, a dry etch, a combination thereof, or the like. Excess portions of the conductive material are removed from the top surface of the dielectric layer DL_{X} using a CMP operation, an etch operation, or combinations thereof to form the source electrode 540 and the drain electrode 550. In some embodiments, a portion of the channel layer 530 at the right side of the gate contact 550 is removed from the insulator layer 520 during the formation of the source electrode 540 and the drain electrode 550. After the forming of the source electrode 540 and the drain electrode 550, the patterned mask layer 720 is removed.

After the formation of the source electrode 540 and the drain electrode 550, a patterned mask layer 730 is formed on the source electrode 540, the drain electrode 550, the gate contact 560 and a portion of the dielectric layer DL_{X} between the source electrode 540 and the drain electrode 550. The formation of the patterned mask layer 730 may include forming a mask layer and a blanket photoresist layer on the source electrode 540 and the drain electrode 550 and patterning the blanket photoresist layer. Patterns of the photoresist layer is then transferred to the mask layer, thereby forming the patterned mask layer 730.

Referring to FIG. 11, an etching operation is performed to cut portions of the channel layer 530 in accordance with step S622 in FIG. 4. The etching operation removes portions of the dielectric layer DL_{X} and the channel layer 530 not covered by the photoresist layer 730. Therefore, multiple trenches 740 are formed. After the etching operation, the source electrode 540 contacts a first end portion of the channel layer 530, and the drain electrode 550 contacts a second end portion of the channel layer 230. The channel layer 530 may have a left sidewall flush with a left sidewall of the source electrode 540. The channel layer 530 may have a right sidewall flush with a right sidewall of the drain electrode 550. The source electrode 540 may have a right sidewall facing a left sidewall of the drain electrode 550. The right sidewall of the source electrode 540 is separated from the left sidewall of the drain electrode 550 by the dielectric layer DL_{X}.

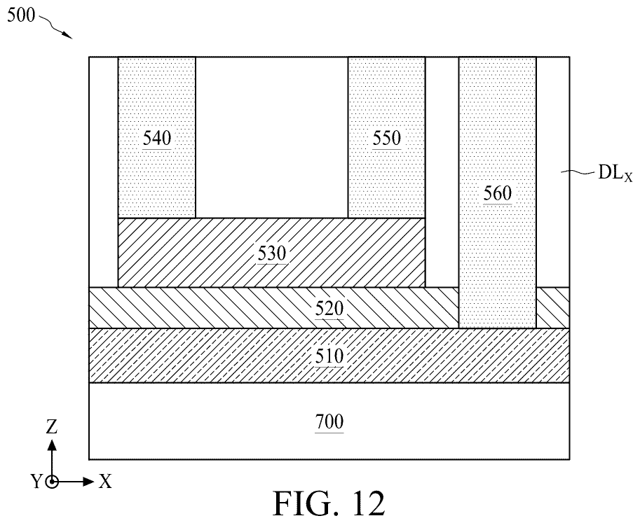

Referring to FIG. 12, a dielectric material is deposited to fill the trenches 740 in accordance with step S624 in FIG. 4. Consequently, the semiconductor device 500 is completely formed on the substrate 710. The dielectric material is formed to fill the trenches 740 around the channel layer 530 using any suitable deposition technique, such as CVD. The dielectric material is same as the material used for the formation of the dielectric layer DL_{X}. A planarization operation may be performed to remove excess portions of the dielectric material from the top surface of the dielectric layer DL_{X}. The planarization operation may include, for example, a CMP operation, a grinding operation, an etching operation, the like, or combinations thereof. In some embodiments, the patterned mask layer 730 may be removed by the planarization process, but the disclosure is not limited thereto.

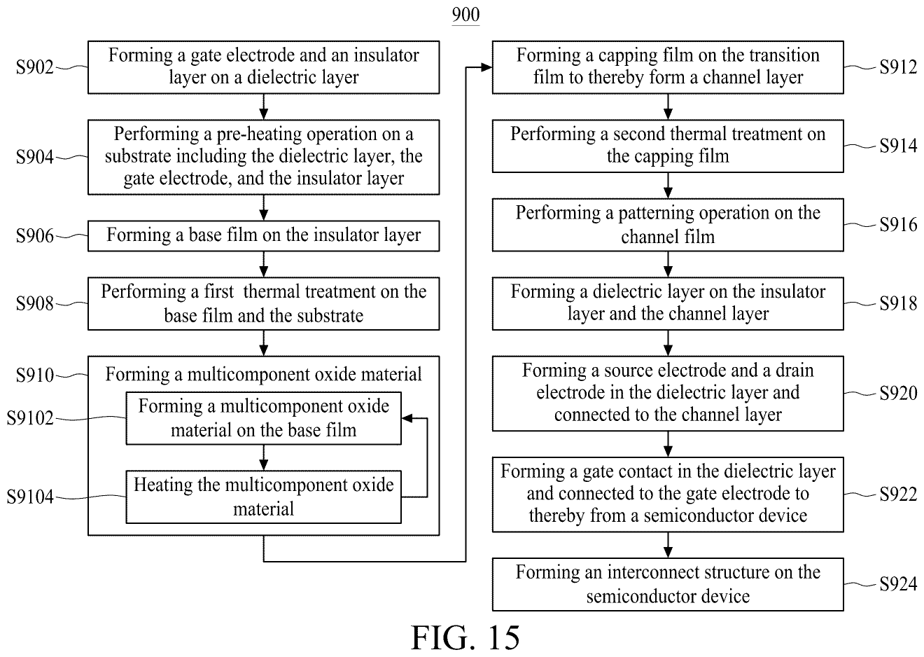

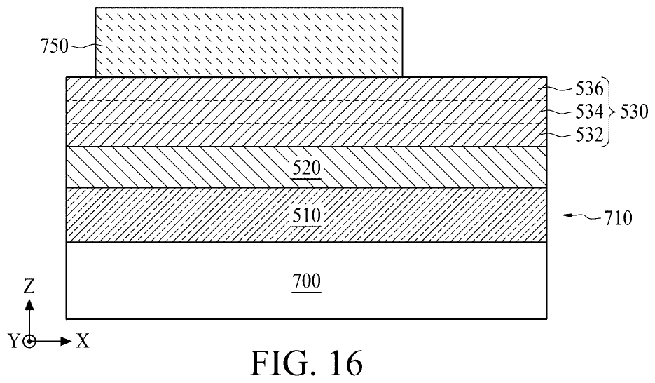

FIG. 15 is a flowchart of a method 900 of manufacturing a semiconductor device 500 and an interconnect structure 1000, in accordance with some embodiments of the present disclosure. FIGS. 16 to 21 are cross-sectional views of intermediate stages of the method 900 of manufacturing the semiconductor device 500 and the interconnect structure 1000, in accordance with some embodiments of the present disclosure. In the following description, the manufacturing stages shown in FIGS. 16 to 21 are discussed with reference to the process steps shown in FIG. 15. It should be understood that additional steps can be provided before, during, and after the steps shown in FIG. 15, and some of the steps described below can be replaced or eliminated, for additional embodiments of the method 900. The order of the steps may be changed.

Referring to FIG. 16, in some embodiments, a gate electrode 510 and an insulator layer 520 are sequentially formed on a dielectric layer 700 in accordance with step S902 in FIG. 15. The dielectric layer 700 may be disposed over a bulk substrate formed with various microelectronic elements. The gate electrode 510 is deposited on the dielectric layer 700. The gate electrode 510 may include a metallic material or a metal compound. The gate electrode 510 may be disposed using any suitable method, such as PVD, CVD, sputtering, plating, or a combination thereof. The insulator layer 520 is deposited on the gate electrode 510 and serves as a gate dielectric of the semiconductor device 500. The insulator layer 520 may include oxide and may be deposited by any suitable method, such as CVD, PVD, ALD, MBE, the like, or a combination thereof. The dielectric layer 700, the gate electrode 510, and the insulator layer 520 are collectively referred to as a substrate 710 hereinafter.

Subsequently, a pre-heat operation is performed on the substrate 710 in accordance with step S904 in FIG. 15. The pre-heat operation is performed to heat at least portions of the substrate 710 to a pre-heat temperature below melting points of the dielectric layer 700, the gate electrode 510, and the insulator layer 520. In some embodiments, the pre-heat operation is performed at a pre-heat temperature in a range from about 300 degrees Celsius to about 400 degrees Celsius. For example, the pre-heat operation is performed at the pre-heat temperature of about 350 degrees Celsius. In some embodiments, the substrate 710 is heated through a suitable heating mechanism, such as infrared radiation. The substrate 710 is pre-heated for the formation of a channel layer 530 with a desired crystallinity. The pre-heat operation may be performed in a thermal chamber 820 shown in FIG. 13.

Still referring to FIGS. 15 and 16, the method proceeds to step S906, in which a base film 532 is formed on the substrate 710. The base film 532 includes IGZO. The base film 532 is deposited by a PVD operation. The PVD operation may be performed in a deposition chamber 810 in FIG. 13. The deposition chamber 810 and the thermal chamber 820 may be positioned in an apparatus 800 of FIG. 13. The thermal chamber 820 and the deposition chamber 810 may be positioned in an apparatus 800 of FIG. 13. The base film 532 is formed using a deposition tool 850 of FIG. 14. The deposition of the base film 532 is performed by sputtering a first target 860 onto the substrate 710. The first target 860 contains indium, gallium, zinc, and oxygen. The first target 860 has a concentration of zinc greater than about 50%. The pre-heat operation may be performed in-situ with the first deposition operation. The base film 532 may include a concentration of zinc of at least 35%.

Subsequently, the substrate 710 with the base film 532 is transported into the thermal chamber 820 shown in FIG. 13. A first thermal treatment is then performed on the base film 532 and the substrate 710 in accordance with step S908 in FIG. 15. The first thermal treatment is performed on the base film 532 to a predetermined temperature at or above a crystallization point of IGZO for improving crystalline quality of the base film 532. The predetermined temperature may be lower than a melting temperature of IGZO. The predetermined temperature is about 200 degrees Celsius.

After the first thermal treatment is completed, the substrate 710 with the base film 532 is transported to the deposition chamber 810 shown in FIG. 13. Subsequently, still referring to FIG. 16, a transition film 534 is formed on the base film 532 in accordance with step S910 in FIG. 15. In some embodiment, the base film 532 and the transition film 534 includes the same elements but different composition ratios. The transition film 534 may include a laminate stack of multiple layers having a multicomponent oxide material (e.g., IGZO) but different composition ratios. In some embodiment, the transition film 534 is formed on the base film 532 by performing a cyclic operation including alternating a deposition step and a heating step. The deposition step may include depositing a multicomponent oxide material on the base film 532 (step S9012 in FIG. 15), and the heating step may include heating the multicomponent oxide material (step S9014 in FIG. 15) at a predetermined temperature (e.g., about 200 degrees Celsius).

In some embodiments, the cyclic operation includes one or more cycles of deposition and heating steps. For example, the deposition and heating steps may be repeated from one to ten cycles. The deposition in the first cycle is performed to form the multicomponent oxide material having a first composition ratio on the base film 532. The deposition in the second cycle is performed to form the multicomponent oxide material having a second composition on the multicomponent oxide material with first composition, wherein the second composition is different from the first composition. The deposition in the third cycle is performed to form the multicomponent oxide material having a third composition different on the multicomponent oxide material with second composition, wherein the second composition is different from the first and second compositions. In some embodiments, a zinc concentration in the multicomponent oxide material may gradually decrease as cycle numbers increases. Further, an indium concentration in the multicomponent oxide material may gradually decrease as cycle numbers increases. By repeating the deposition and heating steps, the desired graded composition profile may be obtained.

The deposition step may be performed in the deposition chamber 810 and the heating step may be performed in the thermal chamber 820 in FIG. 13. The deposition is performed using the deposition tool 850 shown in FIG. 14. Referring to FIG. 14, the deposition may be carried out by sputtering the first target 860 and a second target 870 onto the base film 532. The second target 870 contains indium, gallium, zinc, and oxygen. The second target 870 has a concentration of zinc less than about 25%. In some embodiments, the transition film 534 has a gradient zinc composition profile that decreases at positions of increasing distance from the base film 532. The graded composition includes varying levels of zinc. The varying levels of the zinc may be achieved, for example, by controlling levels of DC power applied to the first target 860 and the second target 870.

The method 900 proceeds to step S912, wherein a capping film 536 is formed on the transition film 534. The capping film 536 may be formed using the deposition tool 850 shown in FIG. 14. The formation of the capping film 536 may be carried out by sputtering the second target 870 onto the transition film 534. The base film 532, the transition film 534, and the capping film 536 are collectively referred to as the channel layer 530. The capping film 536 may have a concentration of zinc equal to or less than about 20%.

After the formation of the capping film 536, the substrate 710 with the channel layer 530 is transported to the thermal chamber 820 shown in FIG. 13. Subsequently, the substrate 710 and the channel layer 530 are subjected to a second thermal treatment in accordance with step S916 in FIG. 15. The second thermal treatment may create a more crystalline structure of the capping film 536. The second thermal treatment may be performed to raise a temperature of the capping film 536 to about 200 degrees Celsius.

Subsequently, a patterned mask layer 750 is formed on at least a portion of the channel layer 530. The formation of the patterned mask layer 750 may include forming a mask layer and a blanket photoresist layer on the channel layer 530 and patterning the blanket photoresist layer. Patterns of the photoresist layer is then transferred to the mask layer, thereby forming the patterned mask layer 750.

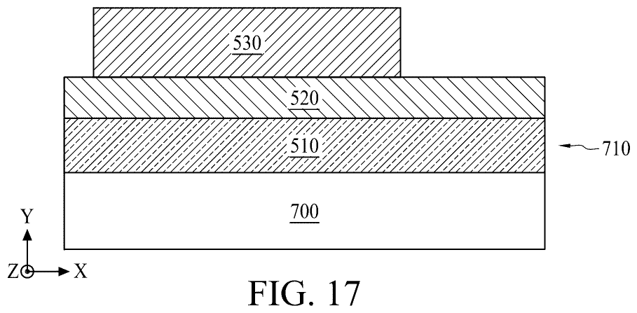

Referring to FIG. 16, an etching operation is performed to pattern the channel layer 530 in accordance with step S916 in FIG. 15. The etching operation removes at least a portion of the channel layer 530 exposed through the patterned mask layer 750. Hence, a length of the channel layer 530 is reduced. Referring to FIG. 17, after the etching operation, the patterned mask layer 750 is removed.

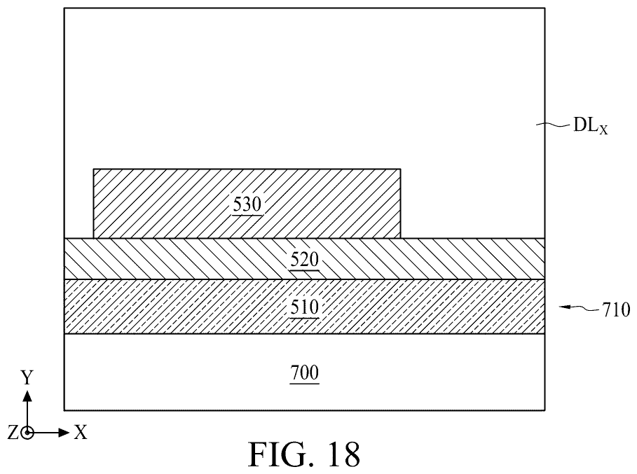

Referring to FIG. 18, a dielectric layer DL_{X} is formed on the insulator layer 520 and the channel layer 530 in accordance with step S98 in FIG. 15. The dielectric layer DL_{X} may be deposited by any suitable method, such as CVD, plasma enhanced CVD (PECVD), a spin-on operation, a combination thereof, or the like. In some embodiments, a planarization operation may be performed to planarize the dielectric layer DL_{X}.

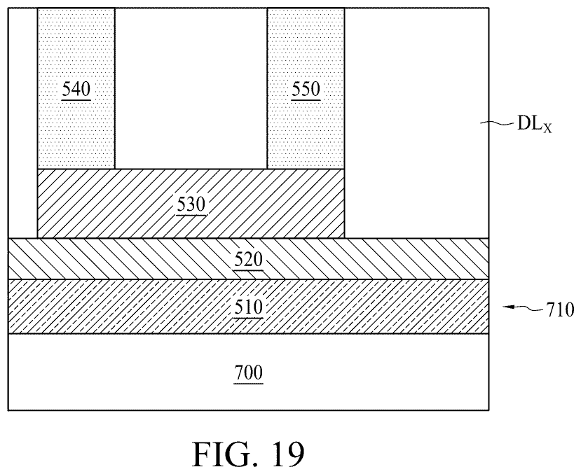

Referring to FIG. 19, a source electrode 540 and a drain electrode 550 are formed to connect to the channel layer 530 in accordance with step S920 in FIG. 15. The formation of the source electrode 540 and the drain electrode 550 may include performing lithography and etching operation to form a plurality of trenches in the dielectric layer DL_{X} to expose portions of the channel layer 530, filling the trenches with a metallic material, and performing a planarization to remove excess metallic material to thereby form the source electrode 540 and the drain electrode 550 in the dielectric layer DL_{X}. After the planarization operation, top surfaces of the source electrode 540 and the drain electrode 550 are exposed through the dielectric layer DL_{X}. The top surfaces of the source electrode 540 and the drain electrode 550 may be flush with an upper surface of the dielectric layer DL_{X}.

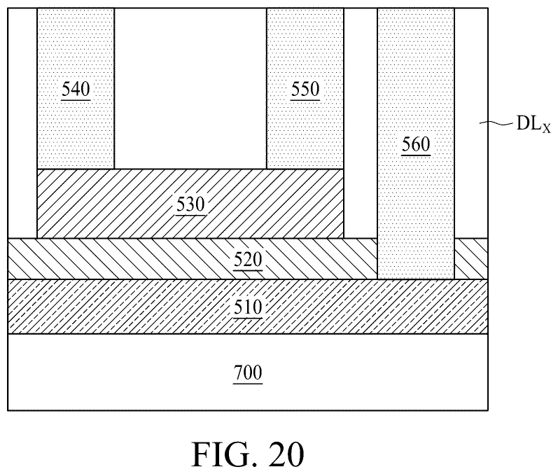

Referring to FIG. 20, a gate contact 560 is formed in the dielectric layer DL_{X}, through the insulator layer, and connected to the gate electrode 510 in accordance with step S922 in FIG. 15. Consequently, the semiconductor device 500 is completely formed on the substrate 710. The gate contact 560 may be formed to penetrate through the dielectric layer DL_{X} and the insulator layer 520 by photolithography and etching operations to form a via trench that exposes a portion of the gate electrode 510, and then filling the via trench with conductive material by deposition, sputtering, plating, or a combination thereof. Excess portions of the conductive material may be removed from the upper surface of the dielectric layer DL_{X} using a CMP operation, an etch operation, or a combination thereof to form the gate contact 560. After the planarization operation, a top surface of the gate contact 560 is exposed through the dielectric layer DL_{X}. The top surfaces of the source electrode 540, the drain electrode 550, and the gate contact 560 may be flush with the upper surface of the dielectric layer DL_{X}.

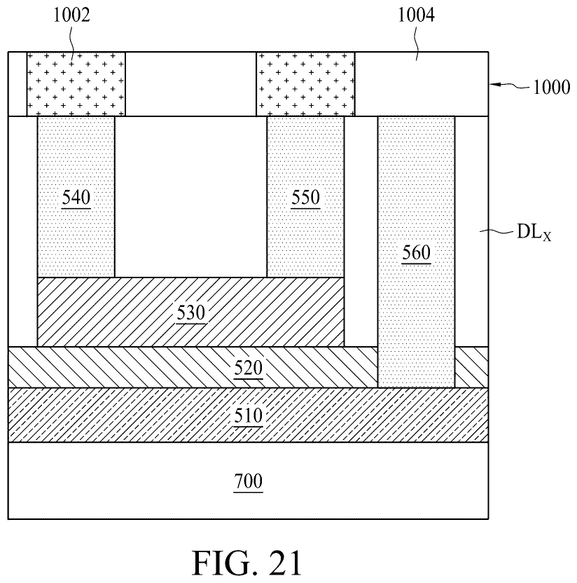

Referring to FIG. 21, an interconnect structure 1000 is formed on the semiconductor device 500 in accordance with step S924 in FIG. 15. In some embodiments, the interconnect structure 1000 may include a plurality of conductive features 1002 and a dielectric layer 1004 laterally surrounding the conductive features 1002. As shown in FIG. 21, one of the conductive features 1002 is connected to the source electrode 540 and another is connected to the drain electrode 550. The present disclosure, however, is not limited thereto. The interconnect structure 1000 may include three conductive features 1002 connected to the source electrode 540, the drain electrode 550, and the gate electrode 560, respectively, when view from a cross-sectional view. The interconnect structure 1000 may be from on the semiconductor device 500 by forming the dielectric layer 1004 to cover the semiconductor device 500, performing lithography and etching operations to form a plurality of trenches in the dielectric layer 1004, filling the trenches with a metallic material, and performing a planarization to remove excess metallic material to thereby form the conductive features 1004.

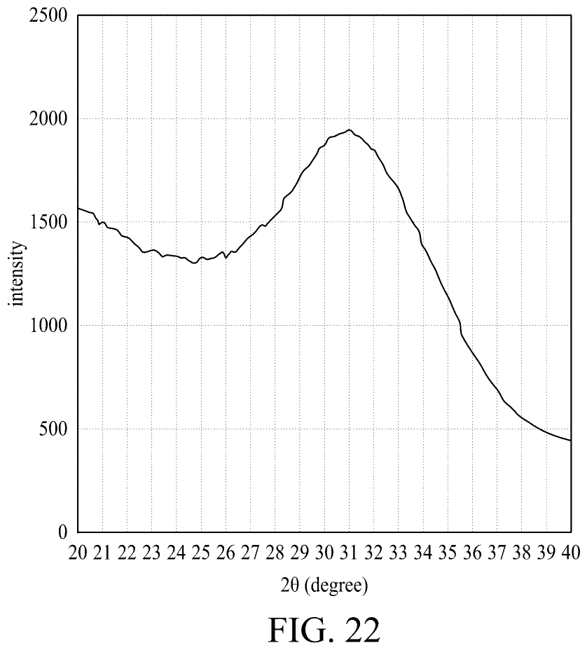

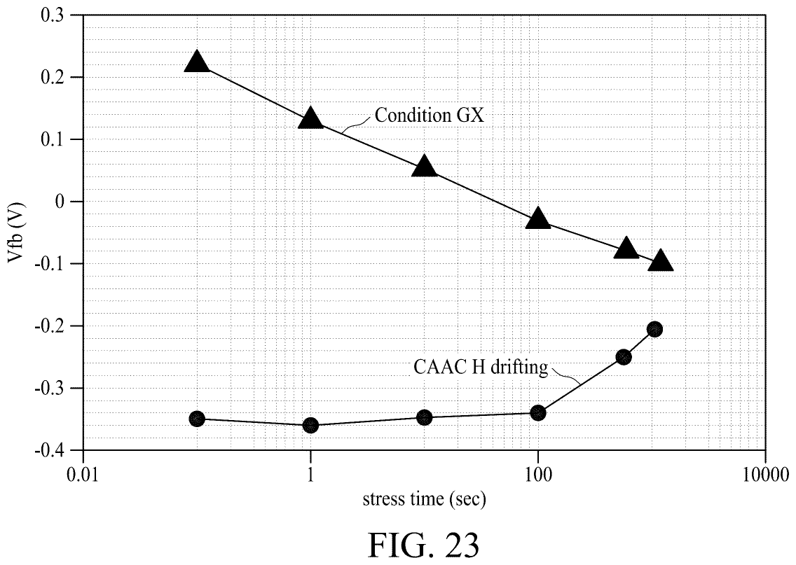

The channel layer 530 formed using the method 600 shown in FIG. 4 or the method 900 shown in FIG. 15 may have an x-ray diffraction (XRD) profile as shown in FIG. 22. Referring to FIG. 22, a peak appears at diffraction angle (2θ) of around 31 degrees, which indicates that crystals in the channel layer 530 have c-axis alignment, and that the c-axes are aligned in a direction substantially perpendicular to the formation surface or the top surface of the channel layer 530. The semiconductor device 500 includes the channel layer 530 structured by CAAC may have a higher reliability as compared with the conventional semiconductor device including an IGZO channel layer with an amorphous structure, as shown in FIG. 23.

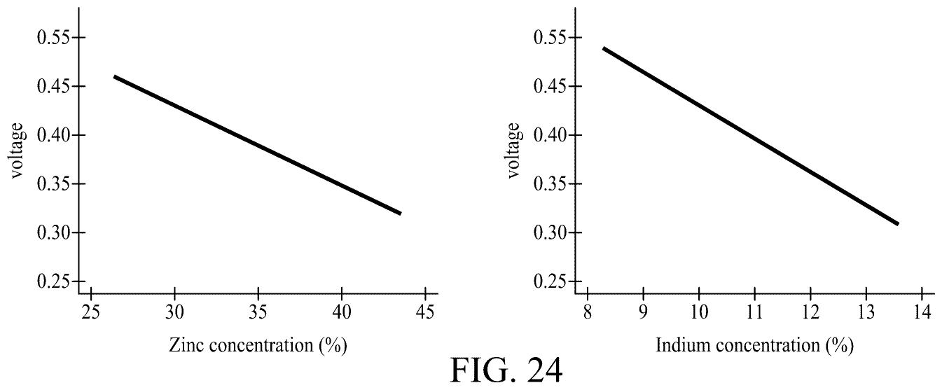

The concentration of zinc and indium in the channel layer 530 may define a threshold voltage of with a higher content in a more negative threshold. FIG. 24 illustrates a change in threshold voltage of exemplary semiconductor device depending on a concentration of zinc and a change in threshold voltage of exemplary semiconductor device depending on a concentration of indium, in accordance with some embodiments of the preset disclosure. It is observed that the change in threshold voltage is inversely linear to the concentration of zinc, and the change in voltage is inversely linear to a concentration of indium. The channel layer 530 having a graded composition of zinc, indium, or both the zinc and indium may move the threshold voltage of the semiconductor device 500 toward a more position direction, comparing with the conversional semiconductor device having the channel layer with a uniform concentration of zinc of about 35%. The threshold voltage of a semiconductor device may be determined by: Vt=1.1-0.03*(In %)−0.01*(Zn %), where In % in the concentration of the indium in the channel layer 530, and Zn % in the concentration of the zinc in the channel layer 530.

In accordance with some embodiments of the present disclosure, a method of fabricating a semiconductor device includes steps of forming a gate electrode on a dielectric layer; forming an insulator layer on the gate electrode; forming a channel layer to cover a portion of the insulator layer, wherein the channel layer comprises a first element from a group 12 and a second element from a group 13 of the periodic table, and a composition of the first element is graded across at least a portion of a thickness of the channel layer; and forming a source electrode and a drain electrode on the channel layer, wherein the source electrode and the drain electrode are separated from each other.

In accordance with some embodiments of the present disclosure, a method of manufacturing a semiconductor device includes steps of depositing a gate electrode on a dielectric layer; depositing an insulator layer on the gate electrode; depositing a base film on the insulator layer; depositing a transition film on the base film, and depositing a capping film over the transition film, wherein the base film, the transition film, and the capping film comprise a first element from a group 12 and a second element from a group 13 of the periodic table, and a composition of the first element is graded across a thickness of the transition film.

In accordance with some embodiments of the present disclosure, a semiconductor device includes a gate electrode; an insulator layer over the gate electrode; a channel layer over the insulator layer, wherein the channel layer comprises a first element from a group 12 and a second element from a group 13 of the periodic table and a composition of the first element is graded across at least a portion of a thickness of the channel layer; and a source electrode and a drain electrode on the channel layer and spaced apart from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming a gate electrode on a first dielectric layer;
forming an insulator layer on the gate electrode;
forming a channel layer to cover a portion of the insulator layer, wherein the channel layer comprises a first element from a group 12 and a second element from a group 13 of the periodic table, and a composition of the first element is graded across at least a portion of a thickness of the channel layer; and
forming a source electrode and a drain electrode on the channel layer, wherein the source electrode and the drain electrode are separated from each other.

2. The method of claim 1, wherein the channel layer comprises at least a c-axis aligned crystal material.

3. The method of claim 1, wherein the formation of the channel layer comprises:
depositing a base film on the insulator layer;
depositing a transition film compositionally graded on the base film; and
depositing a capping film on the transition film, wherein a concentration of the first element in the capping film different from a concentration of the first element in the base film.

4. The method of claim 3, wherein a concentration of the first element in the transition film decreases at positions of increasing distance from the base film.

5. The method of claim 3, wherein a concentration of the second element is graded across the thickness of the transition film.

6. The method of claim 3, further comprising:
performing a pre-heat operation on the insulator layer prior to the deposition of the base film.

7. The method of claim 6, wherein the deposition of the transition film on the base film comprises performing a cyclic operation of alternating a deposition step and a heating step.

8. The method of claim 3, wherein the concentration of the first element in the capping film is less than that in the base film.

9. The method of claim 8, further comprising:
performing a first thermal treatment on the base film prior to the deposition of the transition film; and
performing a second thermal treatment on the capping film after the formation of the capping film.

10. The method of claim 1, wherein the first element is zinc, and the second element is indium.

11. The method of claim 10, wherein the channel layer further comprises gallium and oxygen.

12. The method of claim 1, further comprising:
depositing a second dielectric layer to cover the insulator layer and the channel layer; and
forming a source electrode and a drain electrode in the second dielectric layer and connected to the channel layer, wherein the source electrode and the drain electrode are spaced from each other.

13. A method of manufacturing a semiconductor device, comprising:
depositing a gate electrode on a dielectric layer;
depositing an insulator layer on the gate electrode;
depositing a base film on the insulator layer;
depositing a transition film on the base film; and
depositing a capping film over the transition film,
wherein the base film, the transition film, and the capping film comprise a first element from a group 12 and a second element from a group 13 of the periodic table, and a composition of the first element is graded across a thickness of the transition film.

14. The method of claim 13, wherein the base film, the transition film, and the capping film comprise at least a c-axis aligned crystal material.

15. The method of claim 13, wherein the first element is zinc, and a concentration of zinc decreases at positions of increasing distance from the base film.

16. The method of claim 15, wherein a concentration of zinc in the base film is greater than a concentration of zinc in the capping film.

17. A semiconductor device, comprising:
a gate electrode;
an insulator layer over the gate electrode;
a channel layer over the insulator layer, wherein the channel layer comprises zinc and indium, and a composition of zinc is graded across at least a portion of a thickness of the channel layer; and
a source electrode and a drain electrode disposed on the channel layer, wherein the source electrode and the drain electrode are spaced apart from each other.

18. The semiconductor device of claim 17, wherein the channel layer comprises at least a c-axis aligned crystal material.

19. The semiconductor device of claim 17, wherein the channel layer comprises:
a base film on the insulator layer;
a transition film compositionally graded on the base film; and
a capping film on the transition film,
wherein a concentration of zinc in the transition film decreases at positions of increasing distance from the base film.

20. The semiconductor device of claim 19, wherein a concentration of indium in the transition film decreases at positions of increasing distance from the base film.
